(19) United States
(12) Patent Application Publication
(10) Pub. No.: US 2006/0219170 A1
(43) Pub. Date: Oct. 5, 2006

(54) Pore cathode for the mass production of photovoltaic devices having increased conversion efficiency

(75) Inventor: Stanford R. Ovshinsky, Bloomfield Hills, MI (US)

Correspondence Address: ENERGY CONVERSION DEVICES, INC., 2956 WATERVIEW DRIVE, ROCHESTER HILLS, MI, 48309, US

(73) Assignee: Energy Conversion Devices, Inc.

(21) Appl. No.: 11/447,363

(22) Filed: Jun. 6, 2006

Related U.S. Application Data
(63) Continuation-in-part of application No. 10/043,010, filed on Jan. 11, 2002.

(51) Int. Cl. C23C 16/00

(52) U.S. Cl. 118/715; 118/723 R

(57) ABSTRACT

A pore cathode for use in a deposition chamber for the plasma enhanced deposition of photovoltaic materials onto one or more webs of substrate material. The cathode is planar and serves the dual functions of (1) an electrode for the plasma deposition process and (2) a distribution conduit for the flow of fresh reaction gas to and for the evacuation of the spent reaction gas from the plasma region to maintain a uniform, constant pressure plasma reaction. The gas outlet pores of the inventive cathode are uniquely sized, shaped and spaced to provide new plasma chemistry and physics to insure optimization of the zoo of chemical species within the plasma regardless of deposition speed. That is, the distribution of ions, electrons, free radicals and neutral species in the plasma are optimized to deposit high quality photovoltaic semiconductor material while also increasing the utilization of the process gases, thus allowing the economical mass production of amorphous silicon solar cells having at least 8% photovoltaic efficiency on large area substrates. The pores can be covered by gas dispersion plates which prevent direct, line-of-sight, flow of the process gases to the adjacent deposition substrate and more uniformly distributes the gases flowing into the plasma region between the cathode and the substrate, thus minimizing the effects of non-homogeneity of the depositing species.

### RELATED APPLICATIONS

The present application is a continuation-in-part of U.S. patent application Ser. No. 10/043,010 filed Jan. 11, 2002, the disclosure of which is incorporated herein by reference.

### FIELD OF THE INVENTION

The present invention relates to apparatus and systems which may be utilized to mass-produce thin film semiconductor devices and more specifically to a unique pore cathode which allows for fundamentally new plasma physics and chemistry along with greater uniformity of deposited semiconductor materials in plasma assisted deposition. The size and distribution of the gas outlet pores allows for uniquely synergistic plasma constituent ratios (i.e. the ratio of ions, neutrals and free radicals as well as the composition of the ions, neutrals and free radicals) and sets the boundary conditions for the plasma, resulting in a controlled plasma by utilizing small pore gas outlets from which the plasma is formed. This, in turn, allows for the deposition of photovoltaic semiconductor materials and solar cells having significantly enhanced photovoltaic conversion efficiencies, which, for the first time, has allowed for the production of triple junction solar cells (which permit the collection of a larger portion of the solar spectrum of sunlight) having greater than 8% conversion efficiency on a production apparatus in mass quantities. In addition to providing the proper balance of constituents in the plasma, the pore cathode allows for the higher efficiency of utilization of the process gases in the production of photovoltaic devices, and thus saves money on precious materials and raw material costs. One very costly raw material for which the utilization factor has been significantly increased is the gas germane, thus resulting in significant (about 50%) cost reductions. The pore cathode includes gas dispersion plates which prevent direct, line-of-sight, flow of the process gases to the adjacent deposition substrate and more uniformly distributes the gases flowing into the plasma region between the pore cathode and the substrate.

### BACKGROUND OF THE INVENTION

Crystalline materials which feature a regular lattice structure were formerly considered essential in the manufacture of reliable semiconductor devices. While solar cells, switches and the like having favorable characteristics continue to be so manufactured, it is recognized that preparation of crystalline materials introduces substantial costs into the semiconductor industry. Single crystal silicon and the like must be produced by expensive, energy intensive, high-temperature, time-consuming methods. Czochralski and like crystal growth techniques involve the growth of an ingot which must then be sliced into wafers and are thus inherently batch processing concepts.

Stanford R. Ovshinsky (the instant inventor) pioneered developments in the field of devices formed of amorphous and disordered semiconductors and other materials which offer a significant reduction in production costs. In particular, solar cell technology, which is dependent upon the production of a large number of devices to comprise a panel, is critically affected by processing economies. The feasibility of semiconductor devices produced by amorphous, as opposed to crystalline, materials is disclosed, for example, in U.S. Pat. No. 4,217,374 of Ovshinsky and Izu. A silicon solar cell produced by successive RF plasma glow discharge deposition of layers of various conductivities and dopings and its process of manufacture are described in U.S. Pat. No. 4,226,898 of Ovshinsky and Madan. Both of these prior art patents are hereby incorporated by reference as representative of amorphous semiconductor technology.

The feasibility of amorphous devices becomes apparent in light of the drawbacks inherent in production of crystalline devices. In addition to the aforementioned inherently “batch” nature of crystal growth, a substantial amount of the carefully grown material is lost in the sawing of the ingot into a plurality of useable wafers. Substantial surface finishing and processing effort is often required thereafter. Generally, the production of amorphous devices utilizes batch methods. As in the case of crystalline devices, such production methods impair the economic feasibility of amorphous devices such as solar cells by introducing “dead time” during which valuable equipment sits idle.

As will be discussed more fully herein below, The plasma which creates the devices discussed herein is described as being a “zoo” populated by numerous and rapidly changing exotic activated species of the precursor gaseous mixture introduced thereinto; the species formed by the fragmentation, ionization, radicalization and recombination of that gaseous mixture. It is known that the composition and characteristics of the deposited semiconductor alloy material will depend, inter alia, upon the particular excited species producing that deposit. The present invention gives us a method of controlling the species of this “zoo” to benefit the deposition of desired materials.

Amorphous thin film semiconductor alloys have gained acceptance for the fabrication of electronic devices such as photovoltaic cells, photoresponsive and photoconductive devices, transistors, diodes, integrated circuits, memory arrays and the like. This is because the amorphous thin film semiconductor alloys (1) can now be manufactured by relatively low cost continuous processes, (2) possess a wide range of controllable electrical, optical and structural properties and (3) can be deposited to cover relatively large areas. Among the semiconductor alloy materials exhibiting the greatest present commercial significance are amorphous silicon, germanium and silicon-germanium based alloys (also containing, for example, hydrogen or fluorine). Such alloys have been the subject of a continuing development effort on the part of the assignee of the instant invention, said alloys being investigated and utilized as possible candidates from which to fabricate a wide range of semiconductor, electronic and photoresponsive devices.

The assignee of the present invention is recognized as the world leader in photovoltaic technology. Photovoltaic devices produced by said assignee have set world records for photoconversion efficiency and long term stablility under operating conditions (the efficiency and stability considerations will be discussed in great detail hereinbelow). Additionally, said assignee has developed commercial processes for the continuous roll-to-roll manufacture of large area photovoltaic devices. Such continuous processing systems are disclosed in the following U.S. Patents, disclosures of which are incorporated herein by reference: U.S. Pat. No. 4,400,409, for A Method Of Making P-Doped Silicon Films And Devices Made Therefrom; U.S. Pat. No. 4,410,588, for Continuous Amorphous Solar Cell Production Systems; and U.S. Pat. No. 4,438,723, for Multiple Chamber Deposition and Isolation System And Method. As disclosed in these patents a web of substrate material may be continuously advanced through a succession of operatively interconnected, environmentally protected deposition chambers, wherein each chamber is dedicated to the deposition of a specific layer of semiconductor alloy material onto the web or onto a previously deposited layer. In making a photovoltaic device, for instance, of n-i-p type configurations, the first chamber is dedicated for the deposition of a layer of an n-type semiconductor alloy material, the second chamber is dedicated for the deposition of a layer of substantially intrinsic amorphous semiconductor alloy material, and the third chamber is dedicated for the deposition of a layer of a p-type semiconductor alloy material. The layers of semiconductor alloy material thus deposited in the vacuum envelope of the deposition apparatus may be utilized to form photoresponsive devices, such as, but not limited to, photovoltaic devices which include one or more cascaded n-i-p type cells. By making multiple passes through the succession of deposition chambers, or by providing an additional array of deposition chambers, multiple stacked cells of various configurations may be obtained. Note, that as used herein the term “n-i-p type” will refer to any sequence of n and p or n, i and p semiconductor alloy layers operatively disposed and successively deposited to form a photoactive region wherein charge carriers are generated by the absorbtion of photons from incident radiation.

More particularly, the assignee of the instant invention is presently able to manufacture stacked, large area photovoltaic devices on a commercial basis by utilizing the previously referenced, continuous deposition, roll-to-roll processor. That processor is adapted to produce triple junction photovoltaic cells which comprise three stacked n-i-p type photovoltaic devices disposed optically and electrically in series upon a stainless steel substrate. The processor currently includes operatively interconnected, dedicated deposition chambers, each deposition chamber adapted to sequentially deposit one of the layers of semiconductor alloy material from which the triple junction device is fabricated. The deposition chambers vary in length depending upon the thickness of the particular layer of semiconductor alloy material to be deposited therein.

The thicknesses of individual layers of semiconductor alloy material vary from approximately 100 angstroms for the doped layers to approximately 3500 angstroms for the lowermost intrinsic layer. Since the processor operates by developing an RF plasma which is adapted to decompose the process gases and deposits a layer of semiconductor alloy material and the thickness of the deposited layer is directly dependent upon the residence time of the web of substrate material in the deposition chamber. The processor also includes additional chambers for (1) the payoff and take-up of the web of substrate material, (2) the cleaning of the web of substrate material and (3) preventing interdiffusion of the gaseous contents of the adjacent deposition environments, said interdiffusion prevention preferably occuring in external gas gates.

The assignee of the instant invention has constructed a new and improved semiconductor processing machine for the production of high quantities of photovoltaic energy, about 25 megawatts of electrical power. It must be noted that in order to produce an annual output of 25 megawatts, the length of the machine was increased so that this 25 megawatt processor will be at least an order of magnitude longer than the previous 1.5 megawatt machine. Since not all of the reasons for this increased length are readily apparent, they will be enumerated in the following paragraphs.

A first reason for the elongation is that the new processor is configured to fabricate triple junction photovoltaic devices which comprise three stacked cells; therefore the processor requires nine dedicated deposition chambers. As another factor in determining the length of the processor, and as mentioned previously, the length of each of the individual deposition chambers is dependent upon the thickness of each of the layers of semiconductor alloy material to be deposited thereon. The thickness of that material is, in turn, dependent upon, the rate of deposition of particular mixtures of precursor gases and the speed of the web of substrate material passing through that chamber of the processor.

Unfortunately in the prior art, the rate of deposition of the precursor gas mixture remains constant. Applicant has in the past seen that increasing the rate of deposition of semiconductor alloy material tends to decrease the photovoltaic properties of that material. To prove this, one only needs to speed up (even slightly) the deposition of the amorphous silicon and note that one loses the photovoltaic efficiency very quickly. The prior art has relied on a “sweet spot” to use slow deposition (about two Angstroms per second) to achieve the adequate photovoltaic efficiencies. The mistake of the prior art is that it does not change the chemical and electronic plasma conditions, which means that a different type of plasma is made by only changing the deposition throughput speed (without changing any of the properties/characteristics of the plasma also). However, if one recalibrates the plasma such that it contains the proper amount and ratio of species (such as electrons, ions, neutrals, and radicals) to be constant at any speed, then a revolutionary result is a very low cost, high efficiency process that can challenge the past dogma about the nature of the plasma and lead to production process and products which can be economically competitive to fossil fuel. By bringing down the cost structure of the photovoltaic devices, the present invention can change the world from a polluting, climate changing fuel to a non-polluting, non-CO₂ form of energy which eliminates the need for wars over oil and requires no depletion of non-renewable petrochemical reserves.

The triple junction solar cells made by the present invention provide sufficient voltage to split water to make hydrogen, which can change the world as we know it by serving as a source of energy for automobiles and beyond.

Uniformity and the control of the plasma with a high number of neutrals within the plasma allow for economy of material usage too. For example, in the deposition of a germanium containing thin film, 50% of the cost of the GeH₄ gas used to produced the thin film is saved by confining the GeH₄ gas to a local area. With the present invention, uniformity is guaranteed so that the length and width of the deposition region can be very large (i.e. is scalable). It only takes a few wave fucntions to constrain the boundary conditions.

The present invention allows for the increase of the economy and throughput speed of the photovoltaic deposition with reduced materials costs. Therefore a 30 MW production machine can become a 100 MW machine. Wattage produced from the same machine is significantly increased with no additional capital cost.

The problems of having the proper ratios of species are kept constant to optimize for the specific speed of the deposition machine as well as the type of deposition energy used (i.e. rf or microwave, etc). This invention can also be employed for any specifically attuned plasma. The present invention is particularly useful for quantum confinement of particles and species wherein boundary conditions are controlling wave functions.

The present inventor notes that a plasma is a new state of matter that is difficult to control. The present inventor has shown that plasmas can be controlled even at variable speeds and that problems like powder/chip formation which can significantly effect yield and quality can be significantly eliminated. There are various ways that one can design the internal configuration of the means of deposition to favor the species and ratios thereof that are desired. For example changing the distance from the cathode to the substrate (web) changes the types of species to those that are the most desired. Also in the pores of the cathode themselves, one can have different nozzles releasing gases and mixtures. One can control the plasma by injection electrons, neutrals and charged species there into as needed to optimize the plasma. Even the gas diffusion plates can be configured to help eliminate one type of species or to inject another. Multi-elemental species can be made with great control of process and alloy. The system may use electrical bias to attract or repel charged species and the plasma can further be excited by optical or thermal means and even magnetic fields as well.

The deposition chambers in the 25 megawatt processor are over sixteen times longer than in the previous 1.5 megawatt processor in order to deposit a sufficient quantity of semiconductor alloy material for fabricating photovoltaic devices which provides an annual output of 25 megawatts of electrical power. Even assuming that one foot wide web of substrate material were increased in size to a 2 foot width, a scaled-up version of the prior processor would still total approximately 400 feet in length. Even more significantly, in a deposition apparatus of this size, the cathode utilized for the deposition of the thickest layer of semiconductor alloy material, i.e., the bottommost intrinsic layer of semiconductor alloy material of the triple junction photovoltaic device, is approximately 60 feet in length. Clearly, a 400 foot long processor which requires the incorporation of a 60 foot long cathode presents many problems. Importantly, the large areas covered by some of the deposition cathodes in the 25 megawatt processor creates problems of plasma uniformity and gas utilization within the cathode and deposition regions. Of the foregoing, plasma uniformity poses the most significant problem. Due to the large area plasma regions created by such large area cathodes, non-uniformities in the ionized precursor process gas mixtures arise. More specifically, varying compositions of the activated process gas mixture along the length of a large area cathode will give rise to irregular and nonhomogeneous plasma sub-regions, which irregularities and non-homogeneity will result in the deposition of nonuniform, nonhomogeneous layers of semiconductor alloy material.

In the deposition of large area amorphous photovoltaic materials, uniformity of depositing species is critically important to achieving high efficiency thereof, particularly as the cathode lengths increase. In multi-junction cells this critically is magnified because, if each individual one of the layers of semiconductor alloy material is not uniformly and homogeneously deposited, the overall efficiency of the semiconductor device produced as a conglomeration of those layers suffers. It therefore becomes necessary to carefully control all processing steps which bear on the uniformity, homogeneity and general quality of the deposited semiconductor alloy material.

For example, in the laboratory small area cells can achieve efficiencies on the order of 15%. However, translating this to large area solar cells can prove to be very difficult due, in large part, to inhomogeneity of the depositing species, which in turn can be caused by uneven reactant gas distribution within the deposition plasma. This uneven distribution causes deleterious species to be formed in the plasma and thereafter to be deposited onto the substrate, causing portions of the deposited material to have different properties than those portions which do not have the deleterious species deposited thereon.

These uniformity problems have been addressed in the prior art production of amorphous silicon based photovoltaic arrays. One solution was to distribute the gas more uniformly within the plasma by using a gas distribution cathode for the deposition of such materials onto a moving web of substrate material. Such a gas distribution cathode is disclosed in U.S. Pat. No. 4,369,730 (herein incorporated by reference), which is commonly assigned to the same assignee as the instant invention. While this cathode was useful in its day, it must be improved upon to enhance the efficiencies of large area photovoltaic arrays. The present pore cathode helps prevent depleted species from depositing onto the substrate and to provide a more uniform dispersion of process gas into the adjacent plasma region. Thus, there is a need in the art for such an improved gas distribution cathode.

### SUMMARY OF THE INVENTION

The present invention enhances continuous deposition of photovoltaic modules by providing a pore cathode for use in a plasma deposition chamber of a continuous roll-to-roll deposition system. The cathode of the invention distributes reaction gases in the plasma region bounded by the cathode and the active surface of a substrate. By providing a relatively large area (which may include a number of similar cathode modules used in conjunction with each other) and regular spacings of inlet pores and outlet pores for fresh and spent reaction gases, the device is able to deliver the gases uniformly across the entire active surface of a web-like substrate. The gas outlet pores of the inventive cathode are uniquely sized, shaped and spaced to provide new plasma chemistry and physics that insures the formation of an optimal ratio of ions, electrons, free radicals and neutral species in the plasma (at any deposition rate) to deposit high quality photovoltaic semiconductor material while also increasing the utilization of the process gases, thus allowing the economical mass production of amorphous silicon solar cells having at least 8% photovoltaic efficiency on large area substrates. The pores can be covered by gas dispersion plates which prevent direct, line-of-sight, flow of the process gases to the adjacent deposition substrate and more uniformly distributes the gases flowing into the plasma region between the cathode and the substrate, thus minimizing the effects of non-homogeneity of the depositing species.

Other advantages and features of the present invention will become apparent from the following detailed description wherein like numerals correspond to like features throughout.

### BRIEF DESCRIPTION OF THE FIGURES

FIG. 1 is a schematic depiction of a cross sectional view though the plane of the inventive cathode specifically showing the internal gas distribution manifold;

FIG. 2 is a schematic depiction of a longitudinal cross sectional view of a portion of the inventive cathode depicting the gas outlet pores and gas dispersion plates thereof;

FIG. 3 is a schematic depiction of a transverse cross sectional view of a portion of the inventive cathode which more clearly depicts the relationship between the gas outlet pores and the gas dispersion plates; and

FIG. 4 is a schematic depiction of an overview of the inventive cathode with attached mounting brackets.

### DETAILED DESCRIPTION OF THE INVENTION

The present invention relates to a cathode for a deposition chamber for plasma enhanced deposition of large area, thin film semiconductor materials and deposition chambers incorporating such cathodes. Specifically the cathode is a planar pore cathode which serves the dual functions of (1) an electrode for the plasma deposition process and (2) a distribution conduit for the flow of fresh reaction gas to and for the evacuation of the spent reaction gas from the plasma region to maintain a uniform, constant pressure plasma reaction. The cathode is electrically connected to the RF power source. The cathode is preferably vertically mounted and contains gas dispersion plates to prevents direct, line-of-sight, flow of process gases to the adjacent deposition substrate (which acts as the anode in the deposition) and more uniformly distributes the gases flowing into the plasma region between the cathode and the substrate. By providing a relatively large area (which may include a number of similar cathode modules) and regular spacings of inlet pores and outlet pores for fresh and spent reaction gases, the device is able to deliver the gases uniformly across the entire active surface of a web-like substrate.

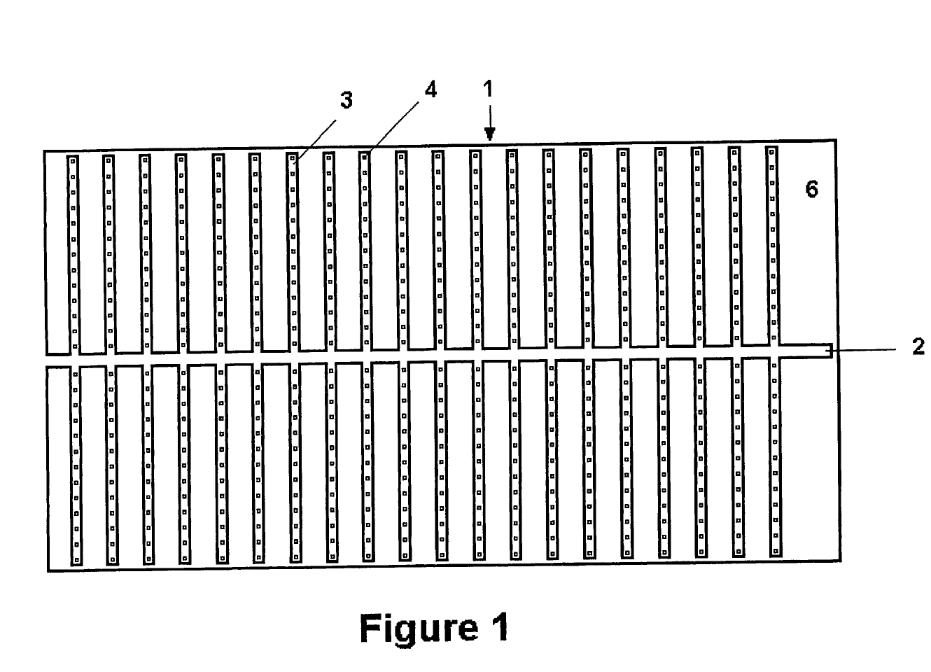

FIG. 1 shows a schematic depiction of a cross sectional view though the plane of the cathode 1. Within the cathode 1, is a main feed gas manifold 2 from which stems a plurality of finger-like secondary gas manifolds 3. A plurality of gas outlet pores 4 are uniformly arranged along the secondary manifolds 3. These gas outlet pores 4 allow gas from the manifold structure to exit the two planar surfaces of the cathode and enter plasma regions adjacent either face of the cathode 1. It is to be understood that the exit ports exist on both surfaces of the planar cathode. The gas outlet pores 4 allow the application of a uniform flow of fresh reaction gas to the surface of a substrate upon which semiconductor material is to be deposited and which also serves as the anode of the plasma deposition process. It should be noted that in this embodiment the gas manifolds are drilled holes within the main body of the cathode 6, but other manifold configurations are possible, such as those in U.S. Pat. No. 4,369,730, herein incorporated by reference.

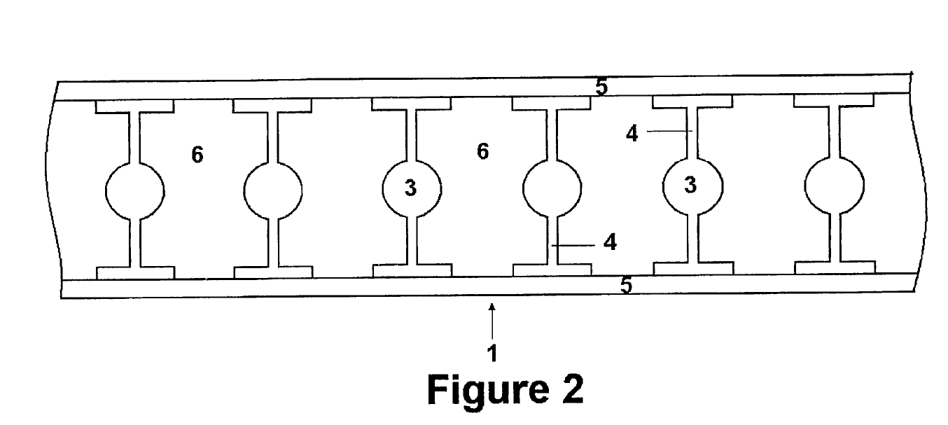

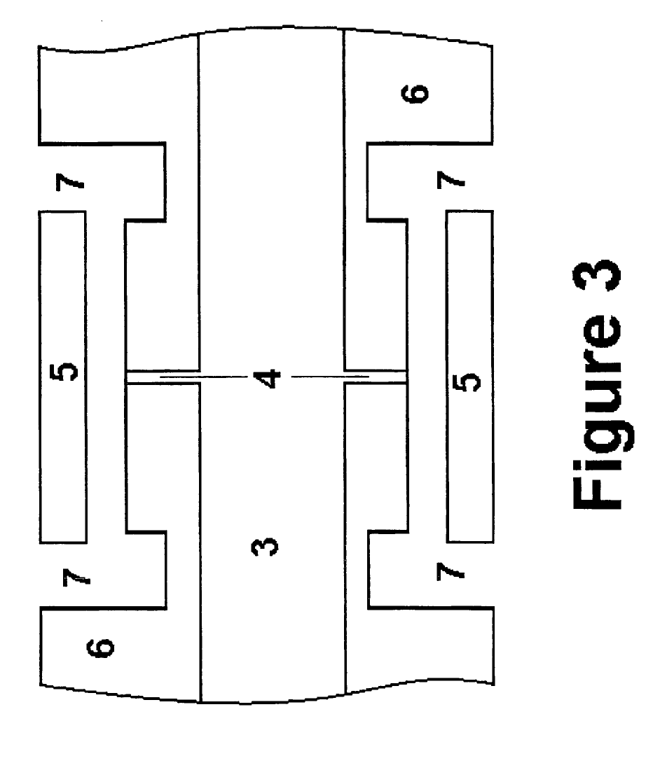

FIG. 2 shows a schematic depiction of a longitudinal cross sectional view of the cathode 1. The finger-like secondary gas manifolds 3 are seen in transverse cross section. The gas outlet pores 4 are covered by gas dispersion plates 5. This gas dispersion plate 5 prevents direct, line-of-sight, flow of the process gases to the adjacent deposition substrate and more uniformly distributes the gases flowing into the plasma region between the cathode and the substrate. The gas dispersion plate 5 is physically and electrically connected to the main body of the cathode 6, but there is a gap around the periphery of the gas dispersion plates 5 (more clearly visible in FIG. 3) though which the gas exits the cathode 1. The gas dispersion plates 5 may be attached to the cathode body 6 via screws or may be welded in place. The gas dispersion plates 5 may cover one or more of the gas outlet pores 4, but should not cover more than one longitudinal or transverse row of gas outlet pores 4. It should be noted that in the schematic depictions of the cathode of the instant invention the gas outlet pores 4 appear as simple drilled holes, however, the gas outlet pores 4 can also be formed by other means, such as, for example, vented screws.

It is believed that the reason previously deposited photovoltaic alloys did not have the desired photovoltaic conversion efficiencies is because (1) the environment in which these amorphous materials have been deposited was contaminated by a great variety of unwanted species and impurities and (2) the previous methods of combining the precursor materials were not effected so as to optimize tetrahedral coordination of the deposited amorphous alloy. The numerous impurities produced by, as well as the parameters involved with, plasma deposition have made it heretofore difficult to deposit high quality photovoltaic materials on large area substrates. The pore cathode of the present invention allows for fabrication of tetrahedrally coordinated, photovoltaic quality amorphous alloy materials on large area substrates that are characterized by a reduced density of defect states in the band gap thereof.

It is known by those skilled in the art of plasma deposition that conditions which exist and the composition of species present within the plasma region are highly complex. Some researchers in the field have even described the plasma as being a “zoo” populated by numerous and rapidly changing exotic activated species of the precursor gaseous mixture introduced thereinto; the species formed by the fragmentation, ionization, radicalization and recombination of that gaseous mixture. It is known that the composition and characteristics of the deposited semiconductor alloy material will depend, inter alia, upon the particular excited species producing that deposit. For instance, certain species favor the deposition of tetrahedrally coordinated semiconductor alloy material, while other species favor the deposition of highly defective material, i.e., material having a significant number of defects, dangling bonds, strained bonds and/or vacancies therein.

Before continuing, it will be helpful to briefly consider some of the plasma kinetics which occur in RF initiated glow discharges. Experimental observations of the electronic defect density of multi-element amorphous silicon alloy films deposited from a great number of different gas chemistries reveal that thin films deposited from combinations of precursor gases having comparable individual “deposition efficiencies” exhibit the highest quality electronic properties. Based upon those observations, it becomes possible to modify the characteristics of the deposited thin film material. However, the degree of modification possible is limited because of the uncontrollable chemistry provided by the “zoo” of chemical reactions generated in the highly energetic plasma. More particularly, in the plasma, the precursor feedstock gases experience multiple collisions with plasma electrons to generate a host of free radicals and ions. It is necessary to pay the most attention to the free radicals which have been generated because experience has demonstrated that free radicals represent the plasma species which is deposited onto a substrate.

With respect to those free radicals, note that there exists a distribution of free radicals depending upon the electron temperature, the electron density and the residence time of the gaseous precursor exposed to the electromagnetic field. The residence time dependence results from multiple electron collisions or collisions between previously excited free radicals and feedstock molecules or between two or more free radicals. In a silane feedstock plasma, the lowest energy member of the possible free radicals which can be generated is SiH₃*, with higher energy members including SiH₂*, SiH* and Si*.

The objective of achieving high quality deposited film is furthered by creating and stabilizing a plasma that is optimized with respect to the concentration, mass and charge of reactive species. Since the quality of the deposited film is correlated with the distribution of species in the plasma, it is necessary to maintain an optimal distribution both spatially and temporally over the entirety of the reaction zone. The prior art has consistently failed to achieve this objective and film quality has suffered as a result.

Since a plasma, in order to be self-sustaining, must contain electrons with sufficient energy to generate ions via collisions with feedstock molecules, and due to the fact that the energy required to generate an ion is generally higher than the energy required to generate the lowest energy member of the free radical spectrum, it is possible to assume that a distribution of free radicals will be created in any plasma. Thus providing a means to control the ratio and chemical composition of these species will provide a technique for depositing high quality amorphous, nanocrystalline and microcrystalline materials and in turn create solar cells with high photovoltaic efficiency.

In the apparatus of the present invention the outlet pores of the cathode are sized and distributed such that collision kinetics of metastable species (of, for example, He or Ar) with neutrals is of the correct energy to favor the formation of the proper radicals (SiH₃*, in the case of a silane feedstock, which SiH₃ free radical is believed by scientists to provide the highest quality silicon alloy material). The reaction products (e.g. SiH₃* and H*) are specific molecular fragments which undergo a chemical vapor deposition reaction on the exposed surface of a heated substrate.

Several unique features of PECVD which are important to a-Si and a-SiGe growth are disclsoed herein below. First, there is an abundance of atomic hydrogen in the a plasma. The atomic hydrogen on the growing surface can remove weak bonds and passivate dangling bonds. Hydrogen is needed in the structure not only to passivate dangling bonds, but to release strain in the tetrahedrally bonded amorphous network. Secondly, the dominant film precursor for a-Si:H deposition from PECVD is generally believed to be SiH₃. This is due to the low reactivity of SiH₃ with the primary discharge gases such as H₂ and SiH₄, which allows it to diffuse to the substrate surface. The advantage of such a low reactivity precursor is that it will have a small probability of surface reaction at the initial point of contact, and thus requires less energy to move around on that surface (i.e. has a low sticking coefficient). This may be one of the reasons that PECVD a-Si:H exhibits the best photovoltaic properties compared to films deposited by other techniques. By analogy to silane chemistry, it is expected that GeH₃ is the dominant precursor for a-Ge:H film. However, GeH₃ is much heavier and diffuses slower than SiH₃. Hence, an a-Ge:H film is much more porous and of poorer quality than an a-Si:H film under the same deposition conditions. Finally, even though free radicals such as SiH, SiH₂, SiH₃, etc. are unable to gain kinetic energy, through elastic collisions with electrons, they can acquire quite high internal energy, in the form of vibrational and rotational energy, through various inelastic collision processes. For example, the vibrational and rotational temperatures of the free radical SiH have been measured from the intensity of the optical emission spectrum. In the electronically excited state, the temperatures are 4000 K and 1800 K, respectively. In the ground state, they are 2000 K and 485 K, respectively. The high internal energy of free radicals is another special feature of PECVD. It had been speculated that because of the high internal energy of free radicals, microcrystalline films can be grown at temperatures below 200° C.

In a-Si:H and/or a-SiGe:H film growth, the precursor species such as GeH₃ and/or SiH₃ arrive at the surface, move around, and locate the most energetically favorable low energy sites, thus forming a thin film on the substrate. Hydrogen elimination and a restructuring of the surface bonds will proceed to complete the growth process. However, energy is required for these processes to occur. The high internal energy of the precursor species may be an important energy source for the successful initiation of these processes. Therefore, techniques which solely heat the gas to increase the translational temperature of the precursor species cannot ensure the fabrication of high quality film. A number of aspects which are critically important to film growth in PECVD can be identified. For example, the abundance of atomic hydrogen, the low reactivity of precursor species and the high internal energy of those species are all important attributes in the growth of a-Si:H and a-SiGe:H films and should be present in the any advanced PECVD technology. A drawback with conventional embodiments of PECVD is the low kinetic temperature of the precursor species which have prevented the growth of high quality a-SiGe alloy films.

It is Applicants' belief that the pore cathode of the present invention is designed to provide a plasma with a greater percentage of the desirable deposition species, which species tend to deposit semiconductor alloy material having high quality photoelectrical properties. It is now a scientifically accepted principle that these high quality photoelectric properties are due, at least in part, to the presence of tetrahedral coordination in depositing material.

Because of the new physics involved in the design of the pore cathode of the present invention, the spacing and size of the gas outlet pores 4 is very important. If the spacing between the gas outlet pores 4 is too large, the uniformity and composition of the deposition plasma is deleteriously affected. The ratio of desirable species to non-desirable and/or spent gas species is changed and the quality of the depositing photovoltaic semiconductor materials is adversely affected. However, if the spacing between the pores is too small, the utilization factor of the process gases is reduced resulting in higher production costs with diminishing returns in photovoltaic efficiency.

Similarly the specifics of pore design effect the fundamentals of the plasma chemistry and physics. The pores are specifically design to provide the proper concentration, ratio and type of ions, electrons, free radicals and neutral species in the plasma to deposit high quality photovoltaic semiconductor material. The specific plasma mix created by the pore cathode of the present invention has allowed for the mass production of triple junction amorphous silicon photovoltaic cells having a photovoltaic conversion efficiency of at least 8%. Previous production machines with different gas distribution cathodes could only produce devices with around 6% efficiency. This improvement is directly related to the gas outlet pores of the inventive cathode and the unique plasma chemistry they provide. The pore size is important, the proper size pores provide the proper plasma chemistry/physics. If the pore size is too large or too small, the plasma chemistry and physics will be negatively affected and the deposited solar cells will be of reduced quality. Also, a unique RF field is created at the boundaries of the pores of the electrode and are thought to play a crucial role in the production and stabilization of a plasma possessing an optimal distribution of species. The shape of the pores (i.e. linear, circular, elliptical, square, etc.) provides an additional degree of freedom for manipulating the distribution of species in the plasma through control of the local RF field in the vicinity of the pore. Thus the RF field created around a plate with no pores will be inadequate to produce the uniquely advantageous plasma chemistry and physics needed to deposit high quality photovoltaic semiconductor material. Further, improper pore design will also reduced the efficiency of gas utilization in the deposition process increasing the cost of production greatly

The present inventor believes that the pore spacing, size and shape creates a plasma which mimics the deposition plasma used in the laboratory to make the best small area amorphous silicon solar cells. The inventor also believes that the specific pore size and shape affects the plasma chemistry and physics in such a way as to provide new plasma physics with the proper distribution of species in the plasma to deposit very high quality photovoltaic material over a large area. The gas outlet pores 4 are evenly spaced on the surfaces of the cathode and are preferably spaced about 1 to 4 inches apart, more preferably about 2 to 3 inches apart.

Further as discussed previously, the plasma includes a multitude of highly excited species, some of which result in the deposition of high quality semiconductor alloy material whereas others of which result in the deposition of low grade semiconductor alloy material. It is also believed by the present inventor that fluorine will aid in organizing the species in the plasma so as to produce a greater number of the optimum deposition species than are ordinarily present. The super halogenicity of fluorine makes it a most efficient promoter of tetrahedral coordination in the absence of contaminants which can compete for the available bonding sites of the host amorphous material.

FIG. 3 shows a schematic depiction of a transverse cross sectional view of the cathode 1. The finger-like secondary gas manifolds 3 are seen in longitudinal cross section. This Figure shows more clearly how the gas outlet pores 4 are covered by the gas dispersion plates 5. This Figure also more clearly depicts how the gas exits the gas outlet pores 4, is deflected and dispersed by the gas dispersion plates 5 and exits from opening 7 between the gas dispersion plates 5 and the cathode body 6.

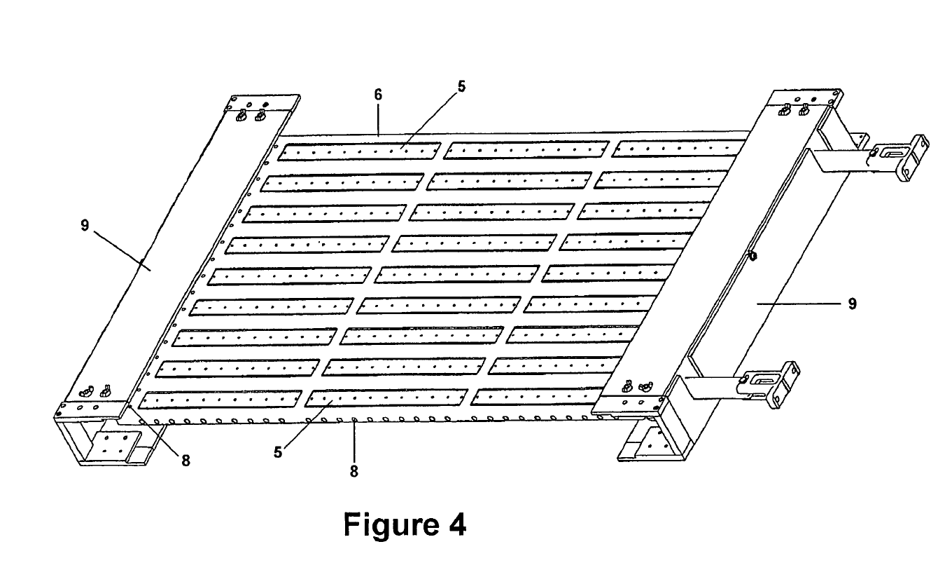

FIG. 4 is a schematic depiction of an overview of the cathode of the present invention with attached mounting brackets 9. From this figure the gas dispersion plates 5 can be clearly seen attached to the main body of the cathode 6. FIG. 4 also indicates spent gas collection inlet pores 8. These inlet pores 8 are attached to a vacuum system which removes spent reactant gases from the plasma region. The inlet pores 8 are attached to an internal spent gas manifold system (not shown) which collects the spent gases and removes them from the deposition system via an exhaust pump (not shown). Preferably the spent gas inlet pores 8 are along at least one longitudinal edge of the main cathode body 6, but can be along one or more of the edges. The spent gas inlet pores 8 can be either along the side edge of the cathode body 6 or along the peripheral edge of the faces of the cathode body 6.

The cathode 1 of the instant invention is designed to be incorporated into a plasma deposition chamber in a vertical manner such that the planar faces of the cathode are perpendicular to the ground. The cathode is designed to create a plasma on both sides thereof and to deposit material on two webs of substrate (or two different portions of the same web) at the same time, however, the instant invention is also applicable to deposition from only a single side of the cathode if so designed or desired. The vertical placement of the cathode deters plasma polymerized species (which degrade photovoltaic devices) from depositing onto the substrate because these species fall, under the influence of gravity, downward and away from the substrate. Also, any deposition on the cathode itself, which eventually spalls and flakes off, will fall downward away from the substrates as well.

Preferably the cathode is made of a metal or metallic alloy which is nonreactive with the various process gases to be introduced into the chamber. One useful metal material is stainless steel. The cathode is preferably adapted to deposit amorphous silicon materials for the production of photovoltaic panels on webs of substrate material using various reaction gases, which may include, an inert gas such as argon or helium, a gaseous compound of silicon such as SiF₄ or silane and at least one modifier element such as germanium, fluorine or hydrogen which acts to reduce the density of localized states in the energy gap to produce a layer of material having electrical properties which closely resemble crystalline silicon.

It should be understood that the present invention is not limited to the precise structure of the illustrated embodiments. It is intended that the foregoing description of the presently preferred embodiments be regarded as an illustration rather than as a limitation of the present invention. It is the claims which follow, including all equivalents, which are intended to define the scope of this invention.

I claim:

1. A gas distribution cathode for plasma enhanced deposition of amorphous, nanocrystalline and microcrystalline silicon photovoltaic materials onto a substrate comprising:
(a) a cathode body having two opposing planar faces; and
(b) a process gas distribution system integrated within said cathode body and including process gas outlet pores which are evenly dispersed on said planar surfaces of said cathode body; said pores being shaped, spaced and sized to provide for the deposition of large area solar cells from a plasma; said plasma characterized in that it contains an optimal ratio of ions, electrons, free radicals and neutral species therein (at any deposition rate) to deposit high quality photovoltaic semiconductor material while also increasing the utilization of the process gases.

2. A gas distribution cathode for plasma enhanced deposition of amorphous, nanocrystalline and microcrystalline silicon photovoltaic materials onto one or more webs of substrate material comprising:
(a) a cathode body having two opposing planar faces; and
(b) a process gas distribution system integrated within said cathode body and including process gas outlet pores which are evenly dispersed on said planar surfaces of said cathode body; said pores being shaped, spaced and sized to provide for the deposition of large area solar cells having at least 8% photovoltaic conversion efficiency.

3. The gas distribution cathode of claim 2, further including one or more gas dispersion plates covering said gas outlet pores so as to prevent direct, line-of-sight travel of precess gas from said gas outlets to a substrate upon which semiconductor material is to be deposited.

4. The gas distribution cathode of claim 2, wherein said process gas distribution system includes at least one primary process gas distribution manifold.

5. The gas distribution cathode of claim 4, wherein said process gas distribution system includes one or more secondary process gas distribution manifolds connected to said primary process gas distribution manifold.

6. The gas distribution cathode of claim 5, wherein said gas outlets are connected to said secondary process gas distribution manifolds.

7. The gas distribution cathode of claim 2, wherein said gas outlets are evenly positioned from 1 to 4 inches apart.

8. The gas distribution cathode of claim 7, wherein said gas outlets are evenly positioned from 2 to 3 inches apart.

9. The gas distribution cathode of claim 2, further including a spent gas evacuation system.

10. The gas distribution cathode of claim 9, wherein said spent gas evacuation system includes spent gas inlets evenly positioned along at least one peripheral edge of said cathode body.

11. The gas distribution cathode of claim 10, wherein said spent gas inlets are connected to a spent gas collection/removal manifold system.

12. The gas distribution cathode of claim 2, wherein said cathode body, said process gas outlets and said gas dispersion plates are formed from a metal or metallic alloy which is non-reactive with said process gases.

13. The gas distribution cathode of claim 12, wherein said cathode body, said process gas outlets and said gas dispersion plates are formed from stainless steel.

14. A deposition apparatus for the plasma enhanced deposition of amorphous silicon photovoltaic materials onto one or more webs of substrate material, said apparatus including: a gas distribution cathode comprising:
(a) a cathode body having two opposing planar surfaces; and
(b) a process gas distribution system integrated within said cathode body and including process gas outlet pores which are evenly dispersed on said planar surfaces of said cathode body; said pores being spaced and sized to provide for the deposition of large area solar cells having at least 8% photovoltaic conversion efficiency.

15. The deposition apparatus of claim 14, further including one or more gas dispersion plates covering said gas outlet pores so as to prevent direct, line-of-sight travel of precess gas from said gas outlets to a substrate upon which semiconductor material is to be deposited.

16. The deposition apparatus of claim 14, wherein said process gas distribution system includes at least one primary process gas distribution manifold.

17. The deposition apparatus of claim 16 wherein said process gas distribution system includes one or more secondary process gas distribution manifolds connected to said primary process gas distribution manifold.

18. The deposition apparatus of claim 17, wherein said gas outlets are connected to said secondary process gas distribution manifolds.

19. The gas distribution cathode of claim 14, wherein said gas outlets are evenly positioned from 1 to 4 inches apart.

20. The deposition apparatus of claim 19, wherein said gas outlets are evenly positioned from 2 to 3 inches apart.

21. The deposition apparatus of claim 14, further including a spent gas evacuation system.

22. The deposition apparatus of claim 21, wherein said spent gas evacuation system includes spent gas inlets evenly positioned along at least one peripheral edge of said cathode body.

23. The deposition apparatus of claim 22, wherein said spent gas inlets are connected to a spent gas collection/removal manifold system.

24. The deposition apparatus of claim 14, wherein said cathode body, said process gas outlets and said gas dispersion plates are formed from a metal or metallic alloy which is non-reactive with said process gases.

25. The deposition apparatus of claim 24, wherein said cathode body, said process gas outlets and said gas dispersion plates are formed from stainless steel.
